(19) United States
(12) Patent Application Publication
(10) Pub. No.: US 2008/0105920 A1
(43) Pub. Date: May 8, 2008

(54) SEMICONDUCTOR DEVICES AND FABRICATION PROCESS THEREOF

(76) Inventors: Tomoyuki Hirano, Kanagawa (JP); Kaori Tai, Kanagawa (JP)

Correspondence Address: David R. Metzger;SONNENSCHEIN NATH & ROSENTHAL LLP, Wacker Drive Station, Sears Towers, Post Office Box 061080, Chicago, IL, 60606-1080, US

(21) Appl. No.: 11/682,586

(22) Filed: Mar. 6, 2007

(30) Foreign Application Priority Data
Mar. 13, 2006 (JP) P2006-067269

(51) Int. Cl. H01L 21/336; H01L 29/78

(52) U.S. Cl. 257/327; 438/294; 257/E21.409; 257/E29.255

(57) ABSTRACT

A semiconductor device has an insulated gate transistor provided with a semiconductor substrate and a gate electrode arranged on the semiconductor substrate via a gate insulating film. The gate electrode includes an electrically-conductive buffer film for preventing any damage, which would occur if a main gate electrode portion were formed directly over the gate insulating film, and the main gate electrode portion formed over the buffer film. A fabrication process for the semiconductor device is also disclosed.

### CROSS REFERENCES TO RELATED APPLICATIONS

The present invention contains subject matter related to Japanese Patent Application JP 2006-067269 filed in the Japanese Patent Office on Mar. 13, 2006, the entire contents of which being incorporated herein by reference.

### BACKGROUND OF THE INVENTION

1. Field of the Invention

This invention relates to semiconductor devices making use of metal gate electrodes, and also to a process for the fabrication of the same.

2. Description of the Related Art

High integration and high-speed operation of MOS transistors have been progressively materialized by their miniaturization on the basis of the scaling laws, and a gate length as short as 0.1 μm is now about to be achieved. Keeping in step with this, thinner gate insulating films have been increasingly adopted. In a transistor with a gate length of 0.1 μm or smaller, for example, it is necessary to reduce the thickness of a gate insulating film to 2 nm or less. This miniaturization has led to devices permitting faster operating speeds at lower power consumption while occupying smaller areas. Recently, it has also been materialized to provide an LSI itself with multifunctions since a greater number of devices can be mounted in the same chip area.

The above-described pursuit for miniaturization is, however, expected to run against brick walls with 0.1 μm being as a boundary. As one of the walls, a limitation is imposed on the reduction in the thickness of a gate oxide film. Silicon oxide (SiO₂) has been used in existing gate insulating films, because this material can meet two requirements that are indispensable for the operation of each device, specifically that substantially no trapped charges are contained and practically no interface state is formed at a boundary with silicon (Si) in a channel portion. Silicon oxide (SiO₂) was also effective for the miniaturization of devices as it permitted readily forming thin films with good controllability.

However, the dielectric constant of silicon oxide (SiO₂) is low (3.9), thereby requiring a film thickness of 3 nm or less to satisfy the performance of transistors in generations of 1 μm and less. At this film thickness, carriers are expected to be transferred through a film by direct tunneling, leading to a problem that an increase may take place in a leak current between the gate and the substrate.

As a gate electrode material, on the other hand, polycrystalline silicon (hereinafter referred to as “Poly-Si”) has been employed in general. As reasons for this, Poly-Si can form a stable interface with a gate insulating film arranged immediately underneath a gate electrode and, owing to the feasibility of an easy introduction of an impurity into Poly-Si by the use of a technique such as implantation or diffusion, Poly-Si can provide an NMOSFET or PMOSFET with an optimal threshold by choosing appropriate element and concentration as to the impurity and forming a gate electrode having an optimal work function value.

In gate electrodes, polycrystalline silicon (Poly-Si) with N-type or P-type dopant added therein is hence used these days. During an operation of a MOS field-effect transistor (MOSFET), however, a problem arises in that in its gate electrode, a depletion layer expands to increase the electrical film thickness. The thickness of a depletion layer is about 0.2 nm in an NMOS transistor or about 0.5 nm in a PMOS transistor. Keeping in step with the move toward the adoption of a thinner insulating film, the percentage of such a depletion layer has increased to result in an unignorable problem. This depletion of the gate electrode is, however, hardly avoidable as Poly-Si is a semiconductor. With a view to resolving this problem, it has been studied to use a metal electrode which would not form such a depletion layer.

When metal gates are formed with a single kind of metal, however, the gate electrodes are provided with the same work function value in both NMOSFET and PMOSFET. Different from the existing Poly-Si gates, it is thus difficult to adjust the work function values of the gate electrodes in NMOSFET and PMOSFET so that no appropriate thresholds are available.

To overcome the above-described shortcoming, it has been proposed to adopt a dual metal gate, that is, to choose different metal materials for NMOSFET and PMOSFET, respectively, so that NMOSFET is provided with a similar work function as N-type Poly-Si while PMOSFET is provided with a similar work function as P-type Poly-Si. For example, metal nitride materials such as titanium nitride (TiN), tantalum nitride (TaN) and hafnium nitride (HfN) are considered to be promising from the viewpoints of heat resistance and oxidation resistance.

For the formation of gate electrodes, film-forming processes such as chemical vapor deposition (CVD) and atomic layer deposition (ALD) are widely employed. In thermal CVD, ammonia (NH₃) is generally used for the introduction of nitrogen (N). Use of a film-forming temperature as high as 400° C. or even higher, however, adds nitrogen into the insulating film to result in a higher interfacial energy level, thereby providing the resulting transistor with deteriorated characteristics and reliability. Setting of the film-forming temperature at lower than 400° C., on the other hand, makes it possible to inhibit the addition of nitrogen into the insulating film, but develops problems of an abnormal growth and a lowered deposition rate upon film formation. For the adoption of a lower film-forming temperature, an ammonia (NH₃) plasma or nitrogen (N₂) plasma is often used. However, nitrogen ions are bombarded onto the insulating film so that nitrogen is added into the insulating film. As a result, the interfacial energy level becomes higher to provide the resulting transistor with deteriorated characteristics and reliability.

As an alternative process for the formation of a metal gate, the adoption of the damascene structure that a gate is formed again subsequent to the removal of a dummy gate formed beforehand has also been studied in addition to the planar structure that the formation of a gate is performed subsequent to the formation of a metal material into a film as in the existing Poly-Si gates [see, for example, Atsushi Yagishita, Tomohiro Saito, Kazuaki Nakajima, Seiji Inumiya, Yasushi Akasaka, Yoshio Ozawa, Gaku Minamihara, Hiroyuki Yano, Katsuhiro Hieda: “High Performance Metal Gate MOSFETs Fabricated by CMP for 0.1 μm Regime,” International Electron Devices Meeting (IEDM), 98-785-788 (1998)].

In the case of the above-described damascene structure, it is desired to perform film formation by a process excellent in coverage, such as CVD or ALD, because the film formation is also applied to the minute gate length. As a metal-based gate material for PMOSFET, titanium nitride (TiN) has been indicated as one of candidates, and titanium nitride (TiN) making use of CVD has been studied. In the case of CVD-TiN, it has been reported that the formation of a film at high temperature leads to a greater gate-leakage current but this problem can be lessened by lowering the film-forming temperature [see, for example, Shinsuke Sakashita, Kenichi Mori, Kazuki Tanaka, Masaharu Mizuno, Masao Inoue, Shinichi Yamanari, Jiro Yugami, Hiroshi Miyatake, and Masahiro Toneda: “Low Temperature Divided CVD Technique for TiN Metal Gate Electrodes of p-MOSFETs,” Extended Abstracts of 2005 International Conference on Solid Devices and Materials, pp. 854 to 855 (2005)].

### SUMMARY OF THE INVENTION

When a metal gate electrode is formed by a thermal film-forming process, for example, thermal CVD, problems arise in that the resulting gate electrode is provided with a higher resistance and moreover, the deposition rate becomes lower. When film formation is performed by a plasma-assisted film-forming process, for example, plasma CVD, on the other hand, a gate electrode having a low resistance and an appropriate work function can be formed at a higher deposition rate than that available in the thermal film formation. However, any attempt to form a gate insulating film with a nitrogen-containing metal material results in the introduction of nitrogen into the gate insulating film. Under the influence of the nitrogen so introduced, a problem arises in that the gate electrode is provided with a higher interfacial energy level. In addition, it is difficult to form a film with an appropriate work function value.

A scope of the present invention is to resolve the above-described problems, specifically to permit the formation of a gate electrode having a low resistance and an appropriate work function value while maintaining low the interfacial energy level of the gate electrode.

In one embodiment of the present invention, there is thus provided a semiconductor device having an insulated gate transistor provided with a semiconductor substrate and a gate electrode arranged on the semiconductor substrate via a gate insulating film, wherein the gate electrode includes: an electrically-conductive buffer film for preventing any damage which would occur if a main gate electrode portion were formed directly over the gate insulating film, and the main gate electrode portion formed over the buffer film.

In the semiconductor device according to the present invention, the buffer film is arranged between the gate insulating film and the main gate electrode portion. Even when the main gate electrode portion has been formed by a plasma-assisted film-forming process, the gate insulating film has, therefore, been protected from any adverse effect of the plasma, for example, the adverse effect of nitrogen introduction. As the main gate electrode portion, it is accordingly possible to use one formed by a plasma-assisted film-forming process. On the other hand, the buffer film is arranged to avoid any adverse effect of the plasma and therefore, is not demanded to be formed thick. The formation of the buffer film, therefore, brings about neither an adverse effect which would otherwise be produced by an increase in resistance nor an adverse effect of an increased film-forming time. A film formed by a thermal film-forming process can be used as the buffer film.

In another embodiment of the present invention, there is also provided a process for the fabrication of a semiconductor having an insulated gate transistor provided with a semiconductor substrate and a gate electrode arranged on the semiconductor substrate via a gate insulating film, the process including the step of forming the gate electrode, wherein the gate-electrode-forming step includes the following steps of: forming an electrically-conductive buffer film for preventing any damage which would occur if a main gate electrode portion were formed directly over the gate insulating film, and forming the main gate electrode portion over the buffer film.

In the fabrication process according to the present invention, the buffer film is formed between the gate insulating film and the main gate electrode portion. Even when the main gate electrode portion is formed by a plasma-assisted film-forming process, the gate insulating film is, therefore, protected from any adverse effect of the plasma, for example, the adverse effect of nitrogen introduction. The main gate electrode portion can, therefore, be formed by a plasma-assisted film-forming process. On the other hand, the buffer film is a film formed to avoid any adverse effect of the plasma and therefore, is not demanded to be formed thick. The formation of the buffer film, therefore, brings about neither an adverse effect which would otherwise be produced by an increase in resistance nor an adverse effect of an increased film-forming time. Moreover, the buffer film can be formed by a thermal film-forming process.

The semiconductor device according to the present invention can use, as the main gate electrode portion, one formed by a plasma-assisted film-forming process, thereby bringing about advantages that the main gate electrode portion can be provided with a reduced resistance while permitting the formation of the gate electrode at a high deposition rate. In addition, the semiconductor device according to the present invention can use, as the buffer film, one formed by a thermal film-forming process, thereby making it possible to obtain a work function value suited for a PMOSFET or NMOSFET while maintaining low the interfacial energy level of the gate electrode.

The fabrication process according to the present invention can form the main gate electrode portion by a plasma-assisted film-forming process without giving a damage to the gate insulating film, thereby bringing about advantages that the main gate electrode portion can be provided with a reduced resistance while permitting the formation of the gate electrode at a high deposition rate. In addition, the fabrication process according to the present invention can form the buffer film by a thermal film-forming process, thereby making it possible to obtain a work function value suited for a PMOSFET or NMOSFET while maintaining low the interfacial energy level of the gate electrode.

### BRIEF DESCRIPTION OF THE DRAWINGS

FIG. 1A is a schematic cross-sectional view of an insulated gate field-effect transistor according to a first embodiment of the present invention, and FIG. 1B is an enlarged fragmentary cross-sectional view of the insulated gate field-effect transistor;

FIG. 2 is a schematic cross-sectional view of a MOSFET with a buried gate structure according to a second embodiment of the present invention;

FIGS. 3A through 3F are schematic, overall or fragmentary, cross-sectional views of a semiconductor device, which includes a MOSFET, in various stages of a fabrication process according to a third embodiment of the present invention;

FIG. 4 is a correlation diagram of work function value vs. film-forming temperature;

FIG. 5 is a C-V characteristic diagram of the semiconductor device obtained by the fabrication process according to the third embodiment of the present invention;

FIG. 6 is a correlation diagram of electron mobility vs. electric field in the semiconductor device obtained by the fabrication process according to the third embodiment of the present invention;

FIG. 7A is a timing chart of gas introductions in a first stage of ALD film formation, and FIG. 7B is a timing chart of gas and plasma introductions in a second stage of the ALD film formation;

FIG. 8 is a correlation diagram of the specific resistance of a titanium nitride film vs. film-forming temperature for different film-forming processes; and

FIGS. 9A through 9C are schematic cross-sectional views of a semiconductor device, which includes a MOSFET having a gate electrode of the damascene structure, in various stages of a fabrication process according to a fourth embodiment of the present invention.

### DETAILED DESCRIPTION OF THE PREFERRED EMBODIMENTS

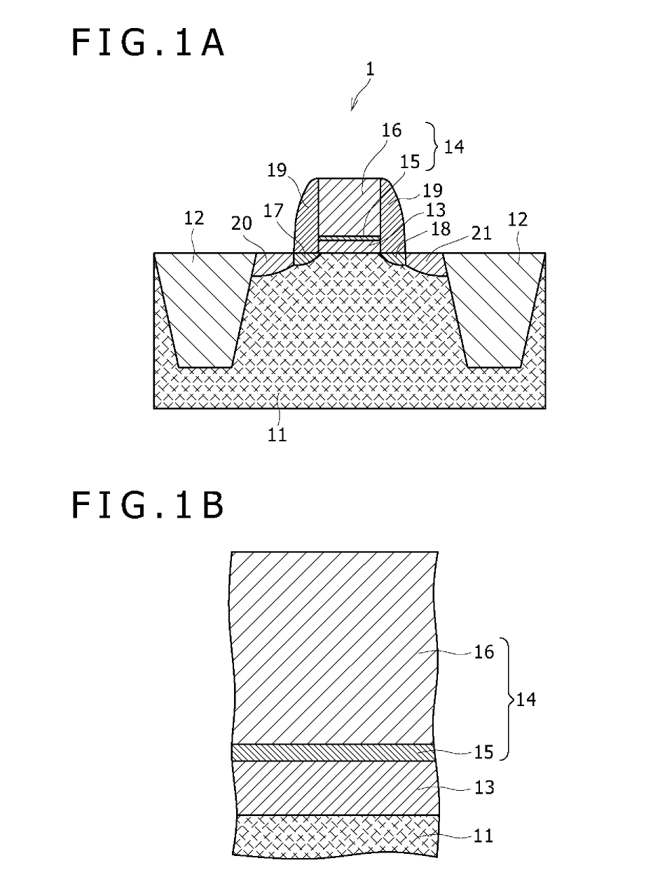

Referring first to FIGS. 1A and 1B, a description will hereinafter be made of an insulated gate field-effect transistor as a semiconductor according to a first embodiment of the present invention.

As illustrated in FIGS. 1A and 1B, a semiconductor device 1 is constructed as will be described below. In a semiconductor substrate 11, insulating regions 12 are formed for the isolation of the resulting device. The semiconductor substrate 11 is formed of a silicon substrate, for example. A gate electrode 14 is formed over the semiconductor substrate 11 with a gate insulating film 13 interposed therebetween. This gate electrode 14 is composed of an electrically-conductive buffer film 15 and a main gate electrode portion 16. Upon formation of the gate electrode 14 as an upper layer, the buffer film 15 serves to prevent any damage to the associated lower layer. For example, the gate insulating film 13 is formed of a silicon oxide (SiO₂) film. As an alternative, the gate insulating film 13 may be formed of a high dielectric film.

The buffer film 15 is a film formed by a thermal film-forming process, and can be made, for example, of a metal nitride such as titanium nitride (TiN), tantalum nitride (TaN), hafnium nitride (HfN), zirconium nitride (ZrN), molybdenum nitride (MoN) or tungsten nitride (WN) or a metal nitride silicide such as titanium nitride silicide (TiSiN), tantalum nitride silicide (TaSiN), hafnium nitride silicide (HfSiN), zirconium nitride silicide (ZrSiN), molybdenum nitride silicide (MoSiN) or tungsten nitride silicide (WSiN) as formed into a film by thermal CVD, thermal ALD (“ALD” is an abbreviation for atomic layer deposition) or the like. The buffer film 15 is formed, for example, with a thickness of from 0.3 nm to 10 nm or so.

The main gate electrode portion 16 is a film formed by a plasma-assisted film-forming process, and can be made, for example, of a metal nitride such as titanium nitride (TiN), tantalum nitride (TaN), hafnium nitride (HfN), zirconium nitride (ZrN), molybdenum nitride (MoN) or tungsten nitride (WN) or a metal nitride silicide such as titanium nitride silicide (TiSiN), tantalum nitride silicide (TaSiN), hafnium nitride silicide (HfSiN), zirconium nitride silicide (ZrSiN), molybdenum nitride silicide (MoSiN) or tungsten nitride silicide (WSiN) as formed into a film by plasma CVD, plasma ALD or the like. The main gate electrode portion 16 is formed, for example, with a thickness of from 10 nm to 100 nm or so.

Further, the buffer film 15 has been controlled at a work function value commensurate with a PMOSFET or NMOSFET.

Extension regions 17, 18 are formed in the semiconductor substrate 11 on opposite sides of the gate electrode 14. In addition, sidewall spacers 19 are formed on sidewalls of the gate electrode 14. Further, source and drain regions 20, 21 are formed in the semiconductor substrate 11 on the opposite sides of the gate electrode 14 such that the extension regions 17, 18 are allowed to remain underneath the sidewall spacers 19. The semiconductor device 1 which includes a MOSFET is constructed as described above.

As the buffer film 15 is arranged between the gate insulating film 13 and the main gate electrode portion 16 in the semiconductor device 1, the gate insulating film 13 was protected from an adverse effect of the plasma, for example, an adverse effect that nitrogen would otherwise have been introduced even when the main gate electrode portion 16 was formed by a plasma-assisted film-forming process. It is thus possible to use, as the main gate electrode portion 16, one formed by a plasma-assisted film-forming process. On the other hand, the buffer film 15 is arranged to avoid any adverse effect of the plasma and therefore, is not demanded to be formed thick. The formation of the buffer film 15, therefore, brings about neither an adverse effect which would otherwise be produced by an increase in resistance nor an adverse effect of an increased film-forming time. A film formed by a thermal film-forming process can be used as the buffer film 15.

The semiconductor device 1 can use, as the main gate electrode portion 16, one formed by a plasma-assisted film-forming process, thereby bringing about advantages that the main gate electrode portion 16 can be provided with a reduced resistance while permitting the formation of the gate electrode 14 at a high deposition rate. In addition, the semiconductor device 1 can use, as the buffer film 15, one formed by a thermal film-forming process, thereby making it possible to obtain a work function value suited for the PMOSFET or NMOSFET while maintaining low the interfacial energy level of the gate electrode 14.

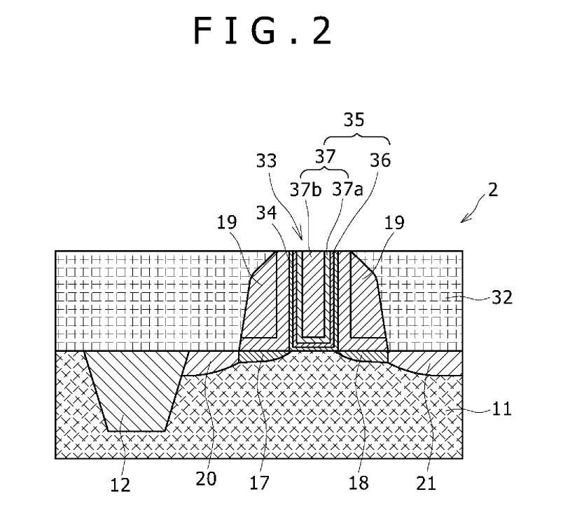

With reference to FIG. 2, a semiconductor device 2 according to a second embodiment of the present invention, which includes a MOSFET with a buried gate structure, will be described next.

As depicted in FIG. 2, an insulating region 12 is formed in a semiconductor substrate 11 to isolate the resulting device. The semiconductor substrate 11 is formed of a silicon substrate, for example. A gate electrode forming trench 33 in which a gate electrode is to be formed is formed over the semiconductor substrate 11. This gate electrode forming trench 33 was formed by forming a dummy electrode (not shown), forming an interlayer insulating film 32, and then removing the dummy electrode.

Extension regions 17, 18 are formed in the semiconductor substrate 11 on opposite sides of the gate electrode forming trench 33. In addition, sidewall spacers 19 are formed on sidewalls of the gate electrode forming trench 33. Further, source and drain regions 20, 21 are formed in the semiconductor substrate 11 such that the extension regions 17, 18 are allowed to remain underneath the sidewall spacers 19.

Inside the gate electrode forming trench 33, a gate electrode 35 is formed via a gate insulating film 34. This gate electrode 35 is composed of an electrically-conductive buffer film 36 and a main gate electrode portion 37. Upon formation of the gate electrode 35 as an upper layer, the buffer film 36 serves to prevent any damage to the associated lower layer. The gate insulating film 34 is formed of a silicon oxide (SiO₂) film, for example. As an alternative, the gate insulating film 34 may be formed of a high dielectric film.

The buffer film 36 is a film formed by a thermal film-forming process, and can be made, for example, of a metal nitride such as titanium nitride (TiN), tantalum nitride (TaN), hafnium nitride (HfN), zirconium nitride (ZrN), molybdenum nitride (MoN) or tungsten nitride (WN) or a metal nitride silicide such as titanium nitride silicide (TiSiN), tantalum nitride silicide (TaSiN), hafnium nitride silicide (HfSiN), zirconium nitride silicide (ZrSiN), molybdenum nitride silicide (MoSiN) or tungsten nitride silicide (WSiN) as formed into a film by thermal CVD, thermal ALD or the like. The buffer film 36 is formed, for example, with a thickness of from 0.5 nm to 10 nm or so. This buffer film 36 has been controlled at a work function value commensurate with a PMOSFET or NMOSFET.

The main gate electrode portion 37 is formed, for example, in two layers. The outer layer 37a of the two layers is a film formed by a plasma-assisted film-forming process, and can be made, for example, of a metal nitride such as titanium nitride (TiN), tantalum nitride (TaN), hafnium nitride (HfN), zirconium nitride (ZrN), molybdenum nitride (MoN) or tungsten nitride (WN) or a metal nitride silicide such as titanium nitride silicide (TiSiN), tantalum nitride silicide (TaSiN), hafnium nitride silicide (HfSiN), zirconium nitride silicide (ZrSiN), molybdenum nitride silicide (MoSiN) or tungsten nitride silicide (WSiN) as formed into a film by plasma CVD, plasma ALD or the like. The main gate electrode portion 37 is formed, for example, with a thickness of from 10 nm to 100 nm or so.

The inner layer 37b of the main gate electrode portion 37 is formed to fill up the remaining cavity of the gate electrode forming trench 33. The inner layer 37b is made of a metal film, for example, a CVD-tungsten (W) film. No particular limitation is imposed on the inner layer 37b insofar as it is a metal-based film having electrical conductivity. It is possible to use, for example, a film of a low-resistance metal-based material such as a metal film, metal nitride film or metal nitride silicide film.

The semiconductor device 2 which includes the MOSFET is constructed as described above. The semiconductor device 2 can bring about similar advantageous effects as the above-described semiconductor device 1 according to the first embodiment.

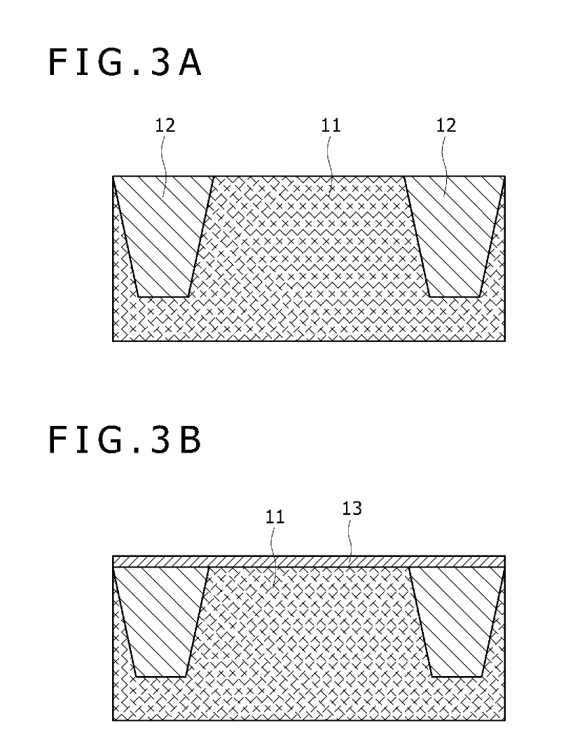

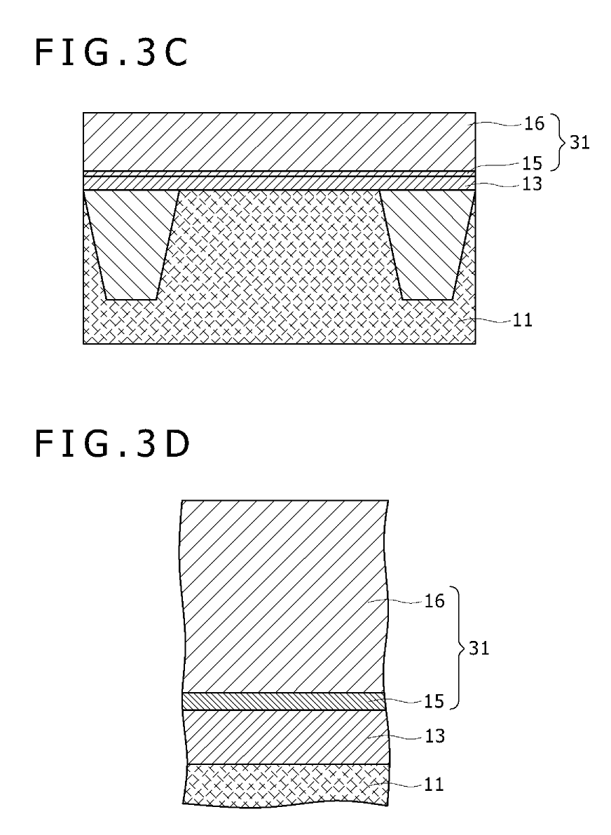

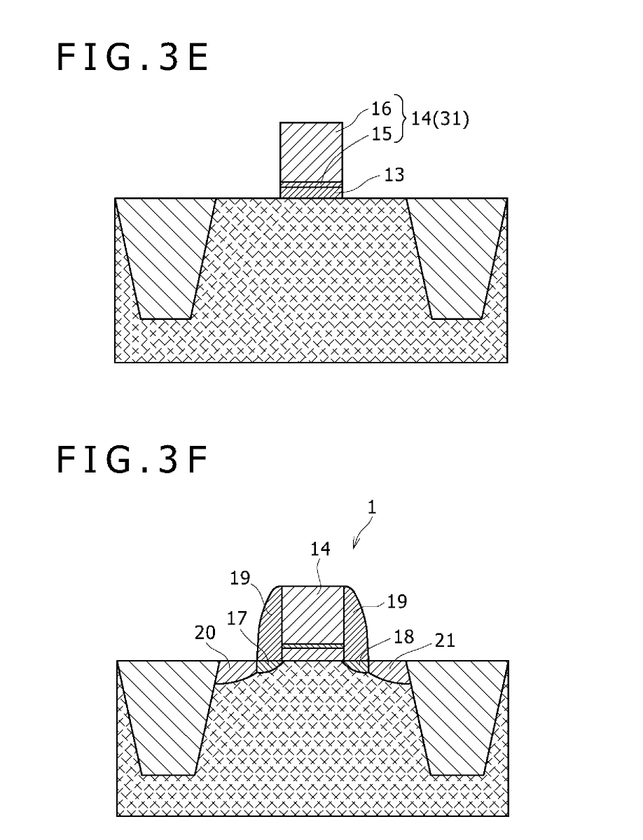

Referring next to FIGS. 3A through 3F, a fabrication process according to a third embodiment of the present invention will be described.

As illustrated in FIG. 3A, gate insulating regions 12 are formed in a semiconductor substrate 11 to isolate the device. As the semiconductor substrate 11, a silicon substrate is used for example. The semiconductor substrate 11 with the insulating regions 12 formed therein is next cleaned at a surface thereof. In this cleaning, the substrate surface is decontaminated with a mixed solution of ammonia, hydrogen peroxide solution and pure water. Subsequently, the substrate 11 with the insulating regions 12 formed therein is dipped for 60 seconds in an aqueous solution of hydrofluoric acid (HF/H₂O: 1/100) to remove a natural oxide film.

As shown in FIG. 3B, a gate insulating film 13 is next formed over the semiconductor substrate 11. As an example of this gate insulating film 13, a thermally grown oxide film (SiO₂ film) can be formed by thermally oxidizing the semiconductor substrate 11. As film-forming conditions, the oxidation temperature may be set at 600° C. to 1,000° C., and the pressure of the film-forming atmosphere may be set at 1.33 Pa to 101 kPa. It is to be noted that the gate insulating film 13 can also be formed with a high dielectric film. In this case, a film-forming process such as CVD or ALD can be adopted.

As depicted in FIGS. 3C and 3D, a gate electrode forming film 31 is next formed over the gate insulating film 13. This gate electrode forming film 31 is composed of an electrically-conductive buffer film 15 and a main gate electrode portion 16 formed over the buffer film 15. Upon formation of the gate electrode as an upper layer over the gate insulating film 13, the buffer film 15 serves to prevent any damage. The gate electrode forming film 31 can be formed with a metal nitride such as titanium nitride (TiN), tantalum nitride (TaN), hafnium nitride (HfN), zirconium nitride (ZrN), molybdenum nitride (MoN) or tungsten nitride (WN) or a metal nitride silicide such as titanium nitride silicide (TiSiN), tantalum nitride silicide (TaSiN), hafnium nitride silicide (HfSiN), zirconium nitride silicide (ZrSiN), molybdenum nitride silicide (MoSiN) or tungsten nitride silicide (WSiN). To form the buffer film 15 and the main gate electrode portion 16, two-stage film formation is performed by different film-forming processes. For example, a thermal film-forming process is adopted for the formation of the buffer film 15, and a plasma-assisted film-forming process is adopted for the formation of the main gate electrode portion 16.

A description will hereinafter be made about an example in which the buffer film 15 is formed with a titanium nitride (TiN) film. In the first-stage film formation, the formation of a film is performed without plasma assistance by setting, for example, the pressure of the film-forming atmosphere and the film-forming temperature (substrate temperature) at 1.33 Pa to 133 kPa and 200° C. to 400° C., respectively, and using as feed gas a mixed gas of titanium tetrachloride (TiCl₄) and ammonia (NH₃). The buffer film 15 may be formed, for example, to a thickness of from 0.3 nm to 1.0 nm or so. At this thickness, effects of the plasma will not extend to the gate insulating film 13 even when plasma-assisted film formation is performed subsequently. Further, the upper limit of the thickness of the buffer film 15, which is higher in electrical resistance than the main gate electrode portion 16, is determined by the tolerance of electrical resistance of the gate electrode 14.

Subsequent to the formation of the buffer film 15, the second-stage film formation is performed. In this second-stage film formation, the formation of the main gate electrode portion 16 is performed by a plasma-assisted film-forming process, for example, plasma CVD. As illustrative film-forming conditions, the pressure of the film-forming atmosphere is set at 1.33 Pa to 133 kPa, the film-forming temperature (substrate temperature) is set at 200° C. to 400° C., a mixed gas of titanium tetrachloride (TiCl₄) and ammonia (NH₃) is used as feed gas, the plasma power is set at 100 W to 600 W, and the main gate electrode portion 16 is formed to a thickness of from 10 nm to 100 nm or so.

By performing thermal film formation in the first stage and plasma-assisted film formation in the second stage as described above, it is possible to inhibit an abnormal growth, which occurs as a problem in a low-temperature process by thermal CVD, and also to avoid, owing to the provision of the buffer film 15, a damage which would otherwise be given by the plasma-assisted film formation.

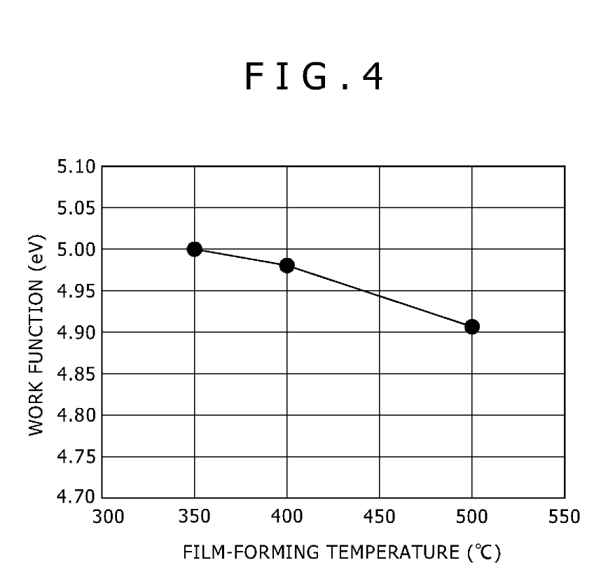

In the above-described film formation, the work function value of the buffer film 15 can be controlled depending on the film-forming temperature. Because the work function value differs depending on the film-forming temperature as indicated in a correlation diagram of work function value vs. film-forming temperature in FIG. 4, an adjustment in the film-forming temperatures makes it possible to perform the film formation such that a desired work function value is obtained. Although FIG. 4 illustrates the correlation of work function value vs. film-forming temperature in the formation of a titanium nitride (TiN), it is also possible to control, depending on the film-forming temperature, the work function value of a film made of a metal nitride such as tantalum nitride (TaN), hafnium nitride (HfN), zirconium nitride (ZrN), molybdenum nitride (MoN) or tungsten nitride (WN) or a metal nitride silicide such as titanium nitride silicide (TiSiN), tantalum nitride silicide (TaSiN), hafnium nitride silicide (HfSiN), zirconium nitride silicide (ZrSiN), molybdenum nitride silicide (MoSiN) or tungsten nitride silicide (WSiN). Reported work function values of the above-described metal-based materials include, for example, 4.5 to 4.6 eV for TaN, 4.3 eV for TaSiN, 4.7 eV for HfN, 4 to 4.7 eV for HfSiN, 4.3 eV for ZrN, 4.7 to 4.8 eV for TiSiN, 4.3 to 4.5 eV for MoSiN, and 5 eV for WN.

As shown in FIG. 3E, a gate electrode 14 is formed by processing the gate electrode forming film 31 in accordance with an existing patterning technology (for example, formation of a mask by a lithographic technique, followed by processing through the mask by a dry etching technique). The gate electrode 14 is, therefore, constructed of the buffer film 15 and the main gate electrode portion 16 on the gate insulating film 13.

As depicted in FIG. 3F, extension regions 17, 18 are next formed in the semiconductor substrate 11 on opposite sides of the gate electrode 14 by an existing transistor forming technique. Sidewall spacers 19 are then formed on sidewalls of the gate electrode 14 by an existing sidewall forming technique. Further, source and drain regions 20, 21 are formed in the semiconductor substrate 11 such that the extension regions 17, 18 are allowed to remain underneath the sidewall spacers 19. The extension regions 17, 18 and the source and drain regions 20, 21 can be formed by a known doping technique, for example, ion implantation or diffusion. Subsequently, activation annealing is performed to form a semiconductor device which includes a MOSFET.

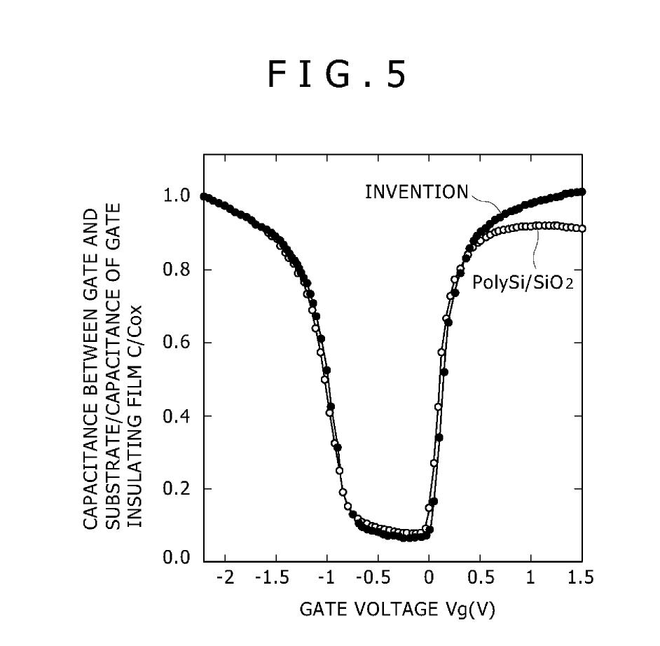

C-V characteristics of the semiconductor device 1 are shown in FIG. 5. In FIG. 5, the ratio (C/Cox) of the capacitance (C) between the gate electrode and the substrate to the capacitance (Cox) of the gate insulating film is plotted along the ordinate, while gate voltage (Vg) is plotted along the abscissa.

As evident from FIG. 5, it is appreciated that a depletion layer, which is observed in a polycrystalline silicon electrode/silicon oxide gate insulating film (Poly-Si/SiO₂), can be eliminated by forming the gate electrode 14 as an electrode of a metal-based material such as titanium nitride.

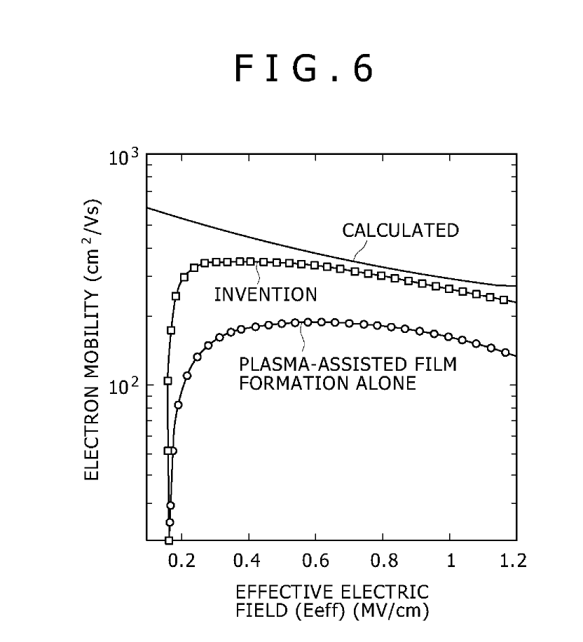

The electron mobility of the semiconductor device (MOSFET) 1 is illustrated in FIG. 6, in which electron mobility is plotted along the ordinate while gate field is plotted along the abscissa.

As apparent from FIG. 6, it is appreciated that compared with a MOSFET having a gate electrode formed only through film formation by plasma CVD, the MOSFET according to the present invention, the MOSFET having the gate electrode 14 including the buffer film 15, takes values close to calculated mobility values. From the results illustrated in FIG. 6, it is understood that good MOSFET characteristics are available from the semiconductor device 1 according to the present invention.

In the formation of the gate electrode forming film 31 described above in connection with the third embodiment, CVD was employed. As an alternative, ALD can also be used. A gate electrode forming film formed by ALD can also bring about similar advantageous effects. A description will hereinafter be made of steps for the formation of a gate electrode by ALD.

In first-stage film formation, the formation of a film is performed by thermal ALD. As illustrative conditions for the film formation, the pressure of a film-forming atmosphere and the film-forming temperature (substrate temperature) are set at 1.33 Pa to 133 kPa and 200° C. to 400° C., respectively. Using titanium tetrachloride (TiCl₄) and ammonia (NH₃) as film-forming gas and argon (Ar) as purge gas, a buffer film 15 is formed to a thickness of from 0.3 nm to 1.0 nm without any plasma assistance. At this thickness, effects of the plasma will not extend to the gate insulating film 13 even when plasma-assisted film formation is performed subsequently. Further, the upper limit of the thickness of the buffer film 15 was set at 1.0 nm, because a thickness of this level is substantially free from increasing the electrical resistance of the gate electrode 14 to be described subsequently herein. Depending on the tolerance of the electrical resistance of the gate electrode, the upper limit of the buffer film 15 may be permitted to increase up to a thickness in such a range that the overall specific resistance of the gate electrode 14 does not exceed, for example, 200 μΩ·cm.

Subsequent to the formation of the buffer film 15, second-stage film formation is performed. In this second-stage film formation, the formation of a main gate electrode portion 16 is performed by plasma-assisted ALD. As illustrative film-forming conditions, the pressure of a film-forming atmosphere is set at 1.33 Pa to 133 kPa, the film-forming temperature (substrate temperature) is set at 200° C. to 400° C., a mixed gas of titanium tetrachloride (TiCl₄) and ammonia (NH₃) is used as feed gas, the plasma power is set at 100 W to 600 W, and the main gate electrode portion 16 is formed to a thickness of from 10 nm to 100 nm or so.

By performing the thermal formation of a film in accordance with ALD in the first stage and performing the formation of a film in accordance with plasma-assisted ALD in the second stage as described above, it is possible to inhibit an abnormal growth, which occurs as a problem in a low-temperature process by thermal ALD, and also to avoid, owing to the provision of the buffer film 15, a damage which would otherwise be given by the plasma-assisted film formation.

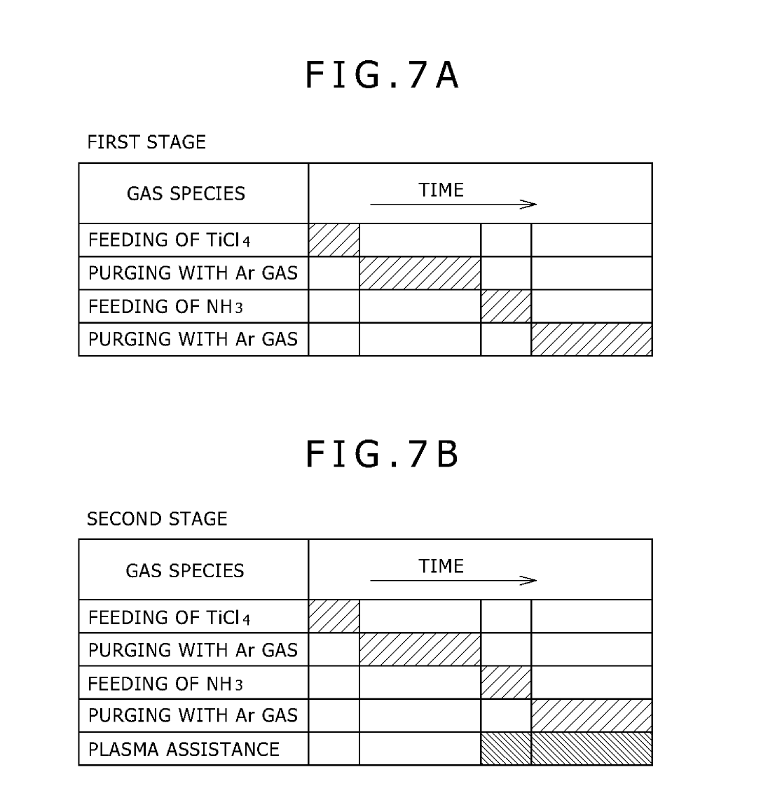

Timings of gas introductions in a first stage of ALD film formation are shown in FIG. 7A, and those of gas and plasma introductions in a second stage of the ALD film formation are illustrated in FIG. 7B. In each of FIGS. 7A and 7B, the ordinate represents steps while the abscissa represents film-forming time.

Reference is first had to FIG. 7A. In the first stage, titanium tetrachloride is firstly fed to form a titanium layer, and subsequently, the feeding of titanium tetrachloride is terminated and the film-forming atmosphere is purged with argon. After completion of the purging with argon, the feeding of argon is terminated, and feeding of ammonia is initiated to form a layer of nitrogen atoms. The feeding of ammonia is then terminated to complete the first formation of the atomic layers. By repeating the formation of the titanium layer and the formation of the nitrogen layer as described above until a predetermined film thickness is achieved, a titanium nitride layer is formed.

Reference is next had to FIG. 7B. In the second stage, titanium tetrachloride is firstly fed to form a titanium layer, and subsequently, the feeding of titanium tetrachloride is terminated and the film-forming atmosphere is purged with argon. After completion of the purging with argon, the feeding of argon is terminated, and feeding of ammonia is initiated to form a layer of nitrogen atoms. This formation of this nitrogen atom layer is performed under the assistance of a plasma. The feeding of ammonia is then terminated and the film-forming atmosphere is purged with argon. During this purging, the plasma assistance is continued to complete the first formation of the atomic layers. By repeating the formation of the titanium layer and the formation of the nitrogen layer as described above until a predetermined overall film thickness is achieved, another titanium nitride layer is formed.

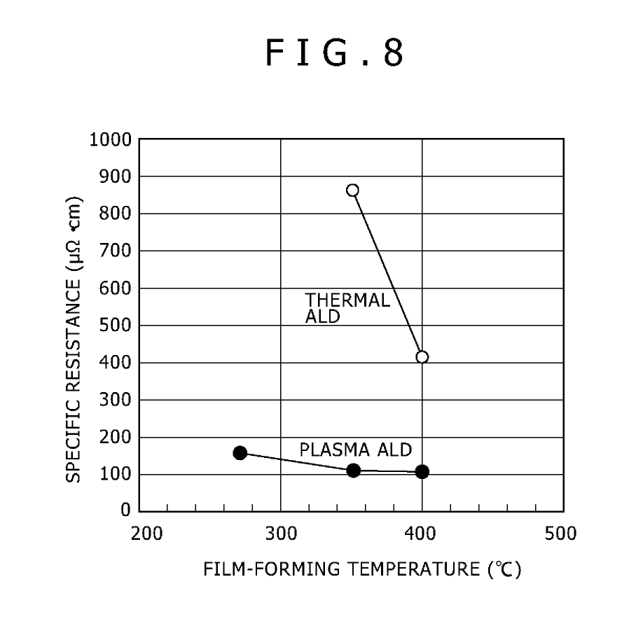

Taking film-forming processes as parameters, correlations of the specific resistance of a titanium nitride (TiN) film vs. the film-forming temperature are next shown in FIG. 8, in which specific resistance is plotted along the ordinate while film-forming temperature is plotted along the abscissa.

As shown in FIG. 8, in the case of the film formed by thermal ALD, its specific resistance is 870 μΩ·cm at the film-forming temperature of 350° C. and is approx. 410 μΩ·cm even at the film-forming temperature of 400° C., so that the film is still provided with a high specific resistance even at a film-forming temperature of 400° C. or lower. In the case of the film formed by plasma ALD, on the other hand, a specific resistance as low as approx. 170 μΩ·cm or lower is obtained at 400° C., 350° C. or even 270° C. As appreciated from the foregoing, a plasma-assisted film-forming process such as plasma ALD or plasma CVD makes it possible to form a film having high density, in other words, a film having low specific resistance. It is, therefore, effective for the formation of a low-resistance gate electrode to form the buffer film 15, which serves to prevent a damage by the plasma, by a thermal film-forming process that does not give such a damage to the gate insulating film 13, such as thermal CVD or thermal ALD, and to use a plasma-assisted film-forming process, such as plasma ALD or plasma CVD, in the formation of the main gate electrode portion 16 which is to be formed in a state that the buffer film 15 has been formed beforehand.

As the buffer film 15 which serves to block the plasma to prevent effects of the plasma from extending to the gate insulating film 13 is arranged between the gate insulating film 13 and the main gate electrode portion 16 in the above-described third embodiment, the gate insulating film 13 is protected from an adverse effect of the plasma, for example, an adverse effect of nitrogen introduction even when the main gate electrode portion 16 is formed by a plasma-assisted film-forming process. Accordingly, the main gate electrode portion 16 can be formed by a plasma-assisted film-forming process, and can be provided as a low-resistance film. On the other hand, the buffer film 15 is arranged to avoid any adverse effect of the plasma and therefore, can have a thin film thickness of 0.3 nm or greater but 10 nm or smaller, and is not demanded to be formed thick. The formation of the buffer film 15, therefore, brings about neither an adverse effect which would otherwise be produced by an increase in resistance nor an adverse effect of an increased film-forming time. The buffer film 15 can, therefore, be formed by a thermal film-forming process which allows to adjust the work function value of the gate electrode 14.

In other words, the main gate electrode portion 16 can be formed by a plasma-assisted film-forming process without giving a damage to the gate insulating film 13, thereby bringing about an advantage that the main gate electrode portion 16 can be provided with a reduced resistance. Another advantage can also be brought about in that the deposition rate of the gate electrode 14 can be rendered higher. In addition, the buffer film 15 can be formed by a thermal film-forming process, thereby making it possible to obtain a suitable work function value while maintaining low the interfacial energy level of the gate electrode 14.

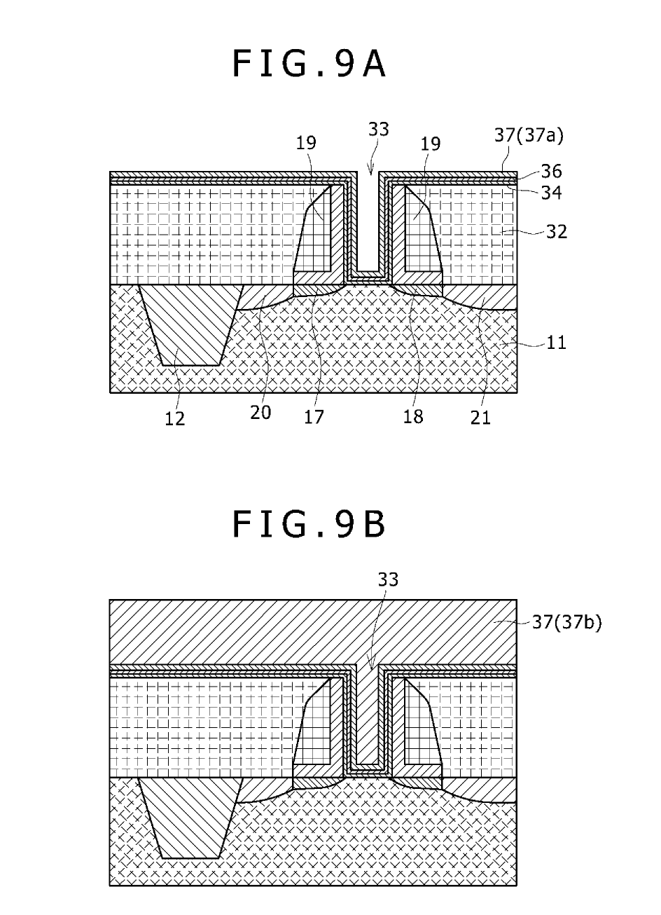

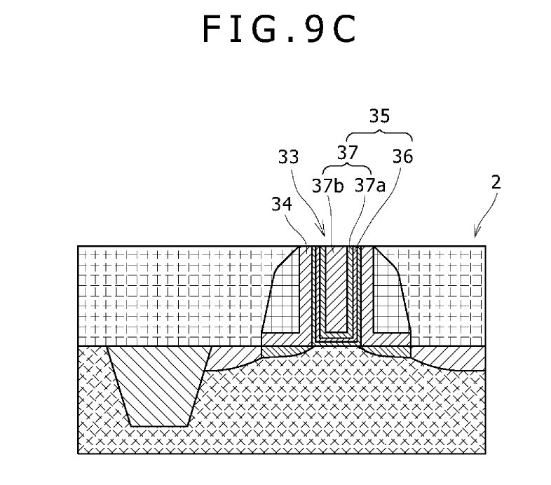

A fabrication process according to a fourth embodiment of the present invention will next be described with reference to FIGS. 9A through 9C.

As illustrated in FIG. 9A, an insulating region 12 is formed in a semiconductor substrate 11 for the isolation of the resulting device. As the semiconductor substrate 11, a silicon substrate is used, for example. A dummy gate (not shown) is next formed over the semiconductor substrate 11, and extension regions 17, 18 are formed in the semiconductor substrate 11 on opposite sides of the dummy gate. Sidewall spacers 19 are then formed on sidewalls of the dummy gate by an existing sidewall forming technique. Further, source and drain regions 20, 21 are formed in the semiconductor substrate 11 such that the extension regions 17, 18 are allowed to remain underneath the sidewall spacers 19. After an interlayer insulating film 32 is formed to cover the dummy gate, the interlayer insulating film 32 is planarized such that the dummy gate is exposed at a top surface thereof. The dummy gate is then removed to form a gate electrode forming trench 33.

A gate insulating film 34 is then formed, followed by the formation of a buffer film 36. This buffer film 36 is formed, for example, by a thermal film-forming process, specifically thermal CVD, thermal ALD or the like. As illustrative conditions for the formation of the buffer film 36 by thermal ALD, the substrate temperature is set at 250° C. to 650° C., the pressure of the film-forming atmosphere is set at 13.3 Pa to 1.33 kPa, and titanium tetrachloride (TiCl₄) diluted with argon (Ar) or the like is introduced. Subsequent to adsorption of titanium tetrachloride (TiCl₄), the film-forming system is evacuated. Ammonia (NH₃) is then introduced, and subsequent to its reaction with the adsorbed titanium tetrachloride (TiCl₄), the film-forming system is evacuated to complete the formation of thermal ALD-TiN. By repeating this sequence, thermal ALD-TiN is formed to a desired film thickness, for example, to 0.5 nm to 10 nm.

Over the surface of the buffer film 36 with the remaining gate electrode forming trench 33 defined as a cavity therein, a main gate electrode portion 37 is formed, for example, in a two-layer structure. Firstly, its outer layer 37a is formed. In this film formation, a plasma-assisted film-forming process is used. For example, plasma ALD or plasma CVD is employed.

As an example, formation of a titanium nitride film by plasma ALD will be described hereinafter. As illustrative conditions for the formation of the titanium nitride film by plasma ALD, the substrate temperature is set at 250° C. to 650° C., the pressure of the film-forming atmosphere is set at 13.3 Pa to 1.33 kPa, and titanium tetrachloride (TiCl₄) diluted with argon (Ar) or the like is introduced. Subsequent to adsorption of titanium (Ti) on the surface of the buffer film 36, the film-forming system is evacuated. By discharging a plasma in an atmosphere of nitrogen (N₂)/hydrogen (H₂) or the like, nitrogen (N) is adsorbed to form plasma ALD-TiN. By repeating the above-described sequence of the titanium tetrachloride (TiCl₄) adsorption and the nitrogen (N) adsorption, plasma ALD-TiN is formed to a desired film thickness, for example, to 0.5 nm to 10 nm. It is in view of coverage property that the lower limit of the film thickness is set greater than that in the third embodiment.

The formation of the titanium nitride (TiN) film by ALD has been described above by way of example. Such a titanium nitride (TiN) film can also be formed likewise with a metal nitride such as tantalum nitride (TaN), hafnium nitride (HfN), zirconium nitride (ZrN), molybdenum nitride (MoN) or tungsten nitride (WN) or a metal nitride silicide such as titanium nitride silicide (TiSiN), tantalum nitride silicide (TaSiN), hafnium nitride silicide (HfSiN), zirconium nitride silicide (ZrSiN), molybdenum nitride silicide (MoSiN) or tungsten nitride silicide (WSiN) as described above in connection with the third embodiment.

As depicted in FIG. 9B, an inner layer 37b of the main gate electrode portion 37 is next formed such that the inner layer 37b fills up the gate electrode forming trench 33 still remaining as a cavity. As an example of the inner layer 37b, a CVD-tungsten (W) film is used in the illustrated embodiment. As illustrative conditions for the formation of the film, the substrate temperature is set at 350° C. to 450° C. and the pressure of the film-forming atmosphere is set at 133 Pa to 13.3 kPa, and the film is formed by using, as process gas, tungsten hexafluoride (WF₆), hydrogen (H₂), monosilane (SiH₄) and the like. No particular limitations are imposed on the species of the filling material and the film-forming process, although the example making use of CVD-tungsten (W) has been described above.

Referring next to FIG. 9C, the gate insulating film 34, buffer film 36, main gate electrode portion 37 and the like formed over the interlayer insulating film 32 (see FIG. 9A) are then removed, for example, by a chemical mechanical polishing (CMP) technology, so that the gate electrode 35 composed of the buffer film 36 and the main gate electrode portion 37 is formed within the gate electrode forming trench 33 with the gate insulating film 34 interposed therebetween. The semiconductor device 2 is fabricated as described above.

When forming such a buried gate structure as described above, the adoption of a film-forming process excellent in coverage property, such as chemical vapor deposition (CVD) or atomic layer deposition (ALD), is desired for performing film formation with good coverage for a short gate length.

In each of the above-described embodiments, titanium nitride (TiN) was described as a metal-based gate material for the PMOSFET. It is also possible to use the above-described metal nitride, metal nitride silicide or the like by making use of the advantage that the work function value can be adjusted depending on the film-forming temperature as described above.

In the above-described forth embodiment, the buffer film 36 is arranged between the gate insulating film 34 and the main gate electrode portion 37 to block a plasma so that effects of the plasma do not extend to the gate insulating film 34. It is, therefore, possible to prevent any adverse effect of a plasma, for example, the adverse effect of nitrogen introduction from extending to the gate insulating film 34 even when the main gate electrode portion 37 is formed by a plasma-assisted film-forming process. Accordingly, the main gate electrode portion 37 can be formed by a plasma-assisted film-forming process, and can be provided as a low-resistance film. On the other hand, the buffer film 36 is arranged to avoid any adverse effect of the plasma and therefore, can have a thin film thickness of 0.3 nm or greater but 10 nm or smaller, and is not demanded to be formed thick. The formation of the buffer film 36, therefore, brings about neither an adverse effect which would otherwise be produced by an increase in resistance nor an adverse effect of an increased film-forming time. The buffer film 36 can, therefore, be formed by a thermal film-forming process which allows to adjust the work function value of the gate electrode 35.

It should be understood by those skilled in the art that various modifications, combinations, sub-combinations and alterations may occur depending on design requirements and other factor in so far as they are within the scope of the appended claims or the equivalents thereof.

What is claimed is:

1. A semiconductor device having an insulated gate transistor provided with a semiconductor substrate and a gate electrode arranged on said semiconductor substrate via a gate insulating film, wherein said gate electrode comprises:
an electrically-conductive buffer film for preventing any damage which would occur if a main gate electrode portion were formed directly over said gate insulating film, and
said main gate electrode portion formed over said buffer film.

2. The semiconductor device according to claim 1, wherein said buffer film includes a film formed by a thermal film-forming process, and said main gate electrode portion includes a film formed by a plasma-assisted film-forming process.

3. The semiconductor device according to claim 1, wherein said buffer film has a work function value commensurate with a work function value of said insulated gate transistor.

4. The semiconductor device according to claim 1, wherein said buffer film includes a film formed by thermal chemical vapor deposition (CVD) or thermal atomic layer deposition (ALD), and said main gate electrode portion includes a film formed by plasma CVD or plasma ALD.

5. The semiconductor device according to claim 1, wherein said main gate electrode portion comprises a nitrogen-containing film.

6. A process for the fabrication of a semiconductor having an insulated gate transistor provided with a semiconductor substrate and a gate electrode arranged on said semiconductor substrate via a gate insulating film, said process including the step of forming said gate electrode, wherein said gate-electrode-forming step comprises the steps of:
forming an electrically-conductive buffer film for preventing any damage which would occur if a main gate electrode portion were formed directly over said gate insulating film, and
forming said main gate electrode portion over said buffer film.

7. The process according to claim 6, wherein said buffer film is formed by a thermal film-forming process, and said main gate electrode portion is formed by a plasma-assisted film-forming process.

8. The process according to claim 6, wherein said buffer film is formed as a film having a work function value commensurate with a work function value of said insulated gate transistor.

9. The process according to claim 6, wherein said buffer film is formed by thermal CVD, and said main gate electrode portion is formed by plasma CVD.

10. The process according to claim 6, wherein said main gate electrode portion is formed using nitrogen-containing gas.
